(19) United States
(12) Patent Application Publication
(10) Pub. No.: US 2009/0185654 A1
(43) Pub. Date: Jul. 23, 2009

(54) Shift circuit capable of reducing current consumption by controlling latch operation

(75) Inventor: Tae Jin Kang, Suwon-si (KR)

Correspondence Address: COOPER & DUNHAM, LLP, 30 Rockefeller Plaza, 20th Floor, NEW YORK, NY, 10112, US

(73) Assignee: Hynix Semiconductor Inc.

(21) Appl. No.: 12/317,217

(22) Filed: Dec. 18, 2008

(30) Foreign Application Priority Data
Jan. 21, 2008 (KR) 10-2008-0006365

(51) Int. Cl. G11C 19/00

(52) U.S. Cl. 377/78; 377/77

(57) ABSTRACT

Disclosed is a shift circuit capable of reducing current consumption and circuit area and increasing the operation speed. The shift circuit includes a transfer unit for transferring input data to a first node in response to a clock signal, and a latch unit for latching the data on the first node in response to a clock signal.

### TECHNICAL FIELD

The present disclosure relates to a semiconductor memory device and, more particularly, to a shift circuit capable of reducing an area and current with a high-speed operation in a semiconductor memory device.

### BACKGROUND

Generally, a shift circuit performs an operation to shift data, which are input in synchronization with a clock signal, and this shift circuit is widely used in a semiconductor memory device. For example, the shift circuit is used as a parallel-serial converter to convert parallel data to serial data and as a delay circuit to delay a signal.

Further, the shift circuit is also used in a synchronous semiconductor memory device because an internal operation timing is determined based on a clock signal.

FIG. 1 is a circuit diagram illustrating a conventional shift circuit and FIG. 2 is a circuit diagram illustrating a feedback inverter employed in the shift circuit of FIG. 1.

As shown in FIG. 1, the conventional shift circuit includes a transfer gate T10 to transfer input data D_IN to a node nd10 in response to a clock signal CLK, a first latch 10 to latch the data transferred to the node nd10, a transfer gate T12 to transfer the input data D_IN on a node nd11 to a node nd12 in response to the clock signal CLK, and a second latch 12 to latch the data transferred to the node nd12.

The first latch 10 includes an inverter IV12 to invert the data on the node nd10 and output the inverted data to the node nd11 and an inverter IV14 to invert the data on the node nd11 and output the inverted data to the node nd10. The second latch 12 includes an inverter IV16 to invert the data on the node nd12 and output the inverted data to the node nd13 and an inverter IV18 to invert the data on the node nd13 and output the inverted data to the node nd12.

In the above-mentioned shift circuit, when the clock signal CLK is at a low level, the input data D_IN is transferred to the node nd10 and the first latch 10 latches the data on the node nd10.

Next, when the clock signal CLK is transited from a low level to a high level, the latched data in the first latch 10 are transferred to the node nd12 and the second latch 12 latches and stores the data on the node nd12. The data stored in the second latch 12 are output as output data D_OUT.

As mentioned above, if the clock signal CLK is at a high level, the shift circuit outputs, as the output data D_OUT, the input data D_IN which are input when the clock signal CLK is at a low level. That is, the output data D_OUT are output by shifting the input data D_IN by a half period of the clock signal. This shift circuit is called “half clock shift circuit.”

As shown in FIG. 2, the inverter IV14 induced in the first latch 10 and the inverter IV18 induced in the second latch 12 (hereinafter referred to as “feedback inverters”) are made up of PMOS transistors P10 and P12, which are connected in series to each other between a supply voltage VCC and an output terminal OUT, and NMOS transistor N10 and N12, which are connected in series to each other between the output terminal OUT and a ground voltage. The reason why the feedback inverter is made up of the PMOS transistor P10 and P12, which are connected in series to each other, and the NMOS transistor N10 and N12, which are connected in series to each other, is that the data are sufficiently latched in the first and second latches 10 and 12 by the increased drivability of the feedback inverters.

### BRIEF SUMMARY

In an aspect of the present disclosure, a shift circuit is provided that is capable of reducing current consumption and circuit area and increasing operation speed.

In an embodiment, a shift circuit includes a transfer unit for transferring input data to a first node in response to a clock signal, and a latch unit for latching the data on the first node in response to a clock signal.

In another embodiment, a shift circuit includes a buffer unit for buffering input data in response to a clock signal, and a latch unit for latching the buffered data from the buffer unit in response to a clock signal.

In another embodiment, a shift circuit includes a transfer buffer for buffering a signal on a first node and transferring the buffered signal to a second node, a feedback buffer for feeding back the buffered signal on the second node to the first node, and a feedback determination unit for determining an operation of the feedback buffer in response to a clock signal.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a circuit diagram illustrating a conventional shift circuit;

FIG. 2 is a circuit diagram illustrating a feedback inverter employed in the shift circuit of FIG. 1.

FIG. 3 is a circuit diagram illustrating an example of a structure of a shift circuit according to an embodiment of the present disclosure;

FIG. 4 is a circuit diagram illustrating an example of a structure of a feedback inverter that can be employed in the shift circuit of FIG. 3; and

FIG. 5 is a circuit diagram illustrating an example of a structure of a shift circuit according to another embodiment of the present disclosure.

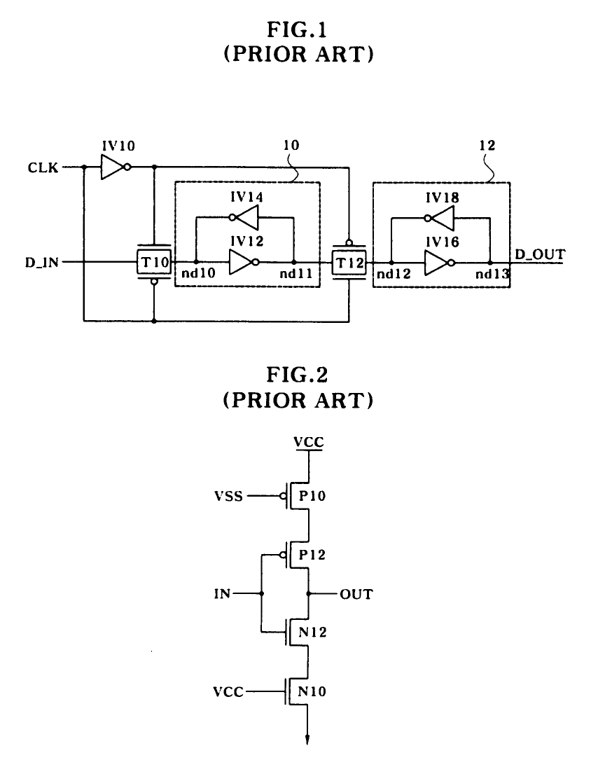

### DETAILED DESCRIPTION OF PREFERRED EMBODIMENTS

Hereinafter, examples and embodiments of the present disclosure will be described with reference to accompanying drawings. However, the examples and embodiments are for illustrative purposes only and are not intended to limit the scope of the invention.

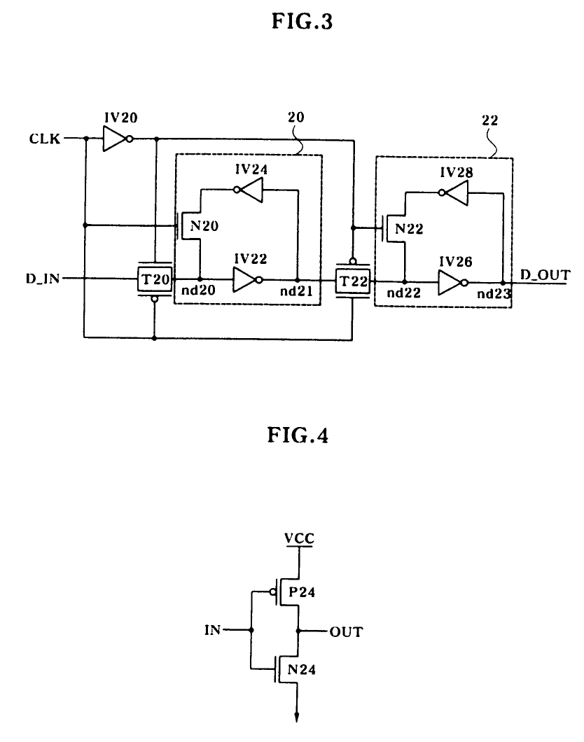

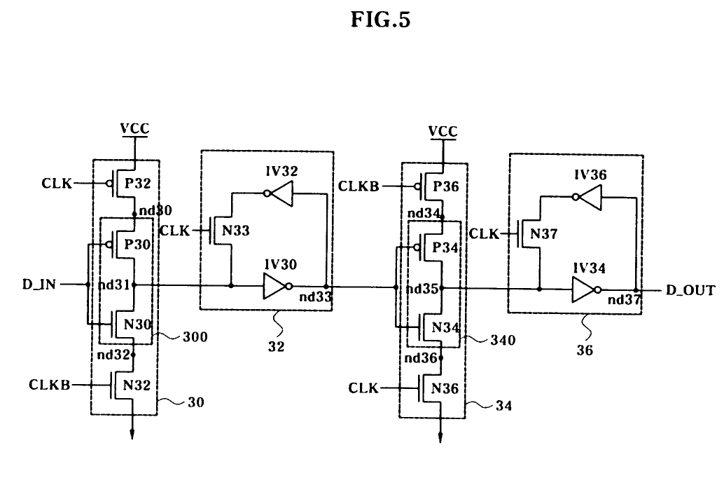

First, FIG. 3 is a circuit diagram illustrating an example of a structure of a shift circuit according to an embodiment of the present disclosure and FIG. 4 is a circuit diagram illustrating an example of a structure of a feedback inverter that can be employed in the shift circuit of FIG. 3.

As shown in FIG. 3, the shift circuit according to an embodiment of the present disclosure includes a first transfer gate T20 configured to transfer input data D_IN to a node nd20 in response to a clock signal CLK, a first latch unit 20 configured to latch the data on the node nd20 in response to the clock signal CLK, a second transfer gate T22 configured to transfer the data on a node nd21 to a node nd22 in response to a clock signal CLK, and a second latch unit 22 configured to latch the data on the node nd22 in response to the clock signal CLK.

The first latch unit 20 includes an inverter IV22 configured to invert the data on the node nd20 and output the inverted data to the node nd21, an inverter IV24 configured to invert the data on the node nd21 and output the inverted data, and a NMOS transistor N20 configured to transfer an output signal of the inverter IV24 to the node nd20 in response to the clock signal CLK.

The second latch unit 22 includes an inverter IV26 configured to invert the data on the node nd22 and output the inverted data to a node nd23, an inverter IV28 configured to invert the data on the node nd23 and output the inverted data, and a NMOS transistor N22 configured to transfer an output signal of the inverter IV28 to the node nd22 in response to the clock signal CLK.

The inverters IV24 and IV28 can be defined as feedback inverters. A feedback inverter, as shown in FIG. 4, includes a PMOS transistor P24, which is disposed between an external supply voltage VCC and an output terminal OUT and performs a pull-up operation at the output terminal OUT in response to an input signal IN, and a NMOS transistor N24, which is disposed between the output terminal OUT and a ground voltage VSS and performs a pull-down operation at the output terminal OUT in response to an input signal IN. As mentioned above, in the feedback inverter according to an embodiment of the present disclosure, the PMOS transistors or NMOS transistors are not connected to each other in series. Since it is not necessary to store the data in the first latch unit 20 and the second latch unit 22 when the data are transferred to another node, the drivability of the first and second latch units 20 and 22 can be sufficiently obtained.

The operation of the above-mentioned shift circuit will be described in detail.

First, when the clock signal CLK is at a low level, the first transfer gate T20 is turned on and then the input data D_IN is transferred to the node nd20. The inverter IV22 inverts the data on the node nd20 and then outputs the inverted data to the node nd21. At this time, the NMOS transistor N20 is turned off and the drivability of the feedback inverter (inverter IV24) is stopped from carrying out the latch operation.

Next, when the clock signal CLK is transited to a high level, the first transfer gate T20 is turned off and the second transfer gate T22 is turned on. Accordingly, the data on the node nd20 are transferred to the node nd22 and the inverter IV26 inverts the data on the node nd22 and outputs the inverted data as the output data D_OUT. At this time, the NMOS transistor N20 is turned on so that the first latch unit 20 latches the data on the node nd20. In this case, the NMOS transistor N22 is turned off so that the inverter IV28, which is used as the feedback inverter, is not connected to the node nd22.

As mentioned above, the shift circuit according to the present disclosure outputs the output data D_OUT by shifting the input data D_IN by a half period of the clock signal and the drivability of the feedback inverter is terminated while the data are transferred to the node. That is, when the input data D_IN are transferred to the node nd20 by the clock signal CLK of a low level, the feedback inverter IV24 does not carry out the driving operation and, when the input data on the node nd21 are transferred to the node nd22 by the clock signal CLK of a high level, the feedback inverter IV28 does not carry out the driving operation. As mentioned above, the drivability of the inverters IV24 and IV28 can be improved, by stopping the driving of the feedback inverters (inverters IV24 and IV28) when the data are transferred in the first and second latch units 20 and 22. Accordingly, since the feedback inverters (inverters IV24 and IV28) are driven whenever the data are stored, the structure of the feedback inverter, according to the present disclosure, can be simplified as shown in FIG. 4. As a result, the area and current consumption of the shift circuit can be reduced and in addition an operation speed can be improved.

FIG. 5 is a circuit diagram illustrating an example of a structure of a shift circuit according to another embodiment of the present disclosure.

As shown in FIG. 5, the shift circuit according to another embodiment of the present disclosure includes a first buffer unit 30 configured to buffer input data D_IN in response to a clock signal CLK, a third latch unit 32 configured to latch the data on a node nd31 in response to a clock signal CLK, a second buffer unit 34 configured to buffer the data D_IN on a node nd33 in response to a clock signal CLK, and a fourth latch unit 36 configured to latch the data on a node nd35 in response to a clock signal CLK.

The first buffer unit 30 includes a first buffer 300, a PMOS transistor P32, and a NMOS transistor N32. The first buffer 300 includes a PMOS transistor P30, which is disposed between a node nd30 and the node nd31 and performs a pull-up operation at the node nd31 in response to the input data D_IN, and a NMOS transistor N30, which is disposed between the node nd31 and a node nd32 and performs a pull-down operation at the node nd31 in response to the input data D_IN. The PMOS transistor P32 is disposed between a supply voltage VCC and the node nd30 and is turned on in response to a clock signal CLK. The NMOS transistor N32 is disposed between the node nd32 and a ground voltage VSS and is turned on in response to an inverted clock signal CLKB.

The third latch unit 32 includes an inverter IV30 configured to invert the data on the node nd31 and output the inverted data to the node nd33, an inverter IV32 configured to invert the data on the node nd33 and output the inverted data, and a NMOS transistor N33 configured to transfer an output signal of the inverter IV32 to the node nd31 in response to the clock signal CLK.

The buffer unit 34 includes a second buffer 340, a PMOS transistor P36, and a NMOS transistor N36. The second buffer 340 includes a PMOS transistor P34, which is disposed between a node nd34 and the node nd35 and performs a pull-up operation at the node nd35 in response to the data D_IN on the node nd33, and a NMOS transistor N34, which is disposed between the node nd35 and a node nd36 and performs a pull-down operation at the node nd35 in response to the data D_IN on the node nd33. The PMOS transistor P36 is disposed between the supply voltage VCC and the node nd34 and is turned on in response to the inverted clock signal CLKB. The NMOS transistor N36 is disposed between the node nd36 and a ground voltage VSS and is turned on in response to the clock signal CLK.

The fourth latch unit 36 includes an inverter IV34 configured to invert the data on the node nd35 and output the inverted data to a node nd37, an inverter IV36 configured to invert the data on the node nd37 and output the inverted data, and a NMOS transistor N37 configured to transfer an output signal of the inverter IV36 to the node nd35 in response to the clock signal CLK.

In FIG. 5, the inverters IV32 and IV36 can be defined as feedback inverters. The feedback inverter, as shown in FIG. 4, includes a PMOS transistor P24, which is disposed between an external supply voltage VCC and an output terminal OUT and performs a pull-up operation at the output terminal OUT in response to an input signal IN, and a NMOS transistor N24, which is disposed between the output terminal OUT and a ground voltage VSS and performs a pull-down operation at the output terminal OUT in response to an input signal IN. As mentioned above, in the feedback inverter according to an embodiment of the present disclosure, the PMOS transistors or NMOS transistors are not connected to each other in series. Since it is not necessary to store the data in the third latch unit 32 and the fourth latch unit 36 when the data are transferred to another node, the drivability of the third and fourth latch units 32 and 36 can be sufficiently obtained.

The operation of the above-mentioned shift circuit will be described in detail.

First, when the clock signal CLK is at a low level, the PMOS transistor P32 and the NMOS transistor N32 are turned on and then the first buffer 300 inverts the input data D_IN and transfers the inverted data to the node nd31. The inverter IV30 inverts the data on the node nd31 and outputs the inverted data to the node nd33. At this time, the NMOS transistor N33 is turned off and the drivability of the feedback inverter (inverter IV32) is stopped from carrying out the latch operation.

Next, when the clock signal CLK is transited to a high level, the PMOS transistor P32 and the NMOS transistor N32 are turned off and the first buffer 300 stops buffering the data. On the other hand, the PMOS transistor P36 and the NMOS transistor N36 are turned on and the second buffer 340 transfers the data on the node nd33 to the node nd35. The data which are transferred to the node nd35 are inverted by the inverter IV34 and the output data D_OUT are output through the node nd37. At this time, the NMOS transistor N33 is turned on, the third latch unit 32 latches and stores the data on the node nd31, and then the NMOS transistor N37 is turned off. Accordingly, the drivability of the feedback inverter (inverter IV36) is stopped from carrying out the latch operation.

As mentioned above, the shift circuit according to the present disclosure outputs the output data D_OUT by shifting the input data D_IN by a half period of the clock signal and the drivability of the feedback inverter is terminated while the data are transferred to the node. That is, when the input data D_IN are transferred to the node nd31 by the clock signal CLK of a low level, the feedback inverter IV32 does not carry out the driving operation and, when the input data on the node nd21 are transferred to the node nd35 by the clock signal CLK of a high level, the feedback inverter IV36 does not carry out the driving operation. As mentioned above, the drivability of the inverters IV32 ad IV36 can be improved, by stopping the driving of the feedback inverters (inverters IV32 and IV36) when the data are transferred in the third and fourth latch units 32 and 36. Accordingly, since the feedback inverters (inverters IV32 and IV36) are driven whenever the data are stored, the structure of the feedback inverter, according to the present disclosure, can be simplified as shown in FIG. 4. As a result, the area and current consumption of the shift circuit can be reduced and in addition an operation speed can be improved.

Although examples and embodiments of the present invention have been described for illustrative purposes, those skilled in the art will appreciate that various modifications, additions and substitutions are possible, without departing from the scope and spirit of the disclosure and the accompanying claims.

The present disclosure claims priority to Korean application number 10-2008-0006365, filed on Jan. 21, 2008, the entire contents of which are incorporated herein by reference.

What is claimed is:

1. A shift circuit comprising:
a transfer unit for transferring input data to a first node in response to a clock signal; and
a latch unit for latching the transferred data on the first node in response to the clock signal.

2. The shift circuit of claim 1, wherein the latch unit includes:
a first inverter for inverting a first signal from the first node and outputting the inverted signal to a second node;
a second inverter for inverting a second signal from the second node; and
a transfer element for transferring an output signal of the second inverter to the first node in response to the clock signal.

3. The shift circuit of claim 2, wherein the second inverter includes:
a pull-up element provided between a power supply voltage terminal and an output node for pull-up driving the output node in response to a signal of the second node; and
a pull-down element provided between the output node and a ground voltage terminal for pull-down driving the output node in response to the signal of the second node.

4. The shift circuit of claim 3, wherein the pull-up element is a PMOS transistor and the pull-down element is a NMOS transistor.

5. The shift circuit of claim 2, wherein the transfer element is provided between an output terminal of the second inverter and the first node and is turned on in response to the clock signal.

6. A shift circuit comprising:
a buffer unit for buffering input data in response to a clock signal and outputting buffered data; and
a latch unit for latching the buffered data from the buffer unit in response to the clock signal.

7. The shift circuit of claim 6, wherein the buffer unit includes:
a buffer for buffering the input data; and
a driving unit for driving the buffer in response to the clock signal.

8. The shift circuit of claim 7, wherein the buffer includes:
a pull-up element provided between a first node and a second node for pull-up driving the second node in response to the input data; and
a pull-down element provided between the second node and a third node for pull-down driving the second node in response to the input data.

9. The shift circuit of claim 8, wherein the driving unit includes:
a first switch provided between a power supply voltage terminal and the first node, wherein the first switch is turned on in response to the clock signal; and
a second switch provided between the third node and a ground voltage terminal, wherein the second switch is turned on in response to the clock signal.

10. The shift circuit of claim 9, wherein the first switch is a PMOS transistor.

11. The shift circuit of claim 9, wherein the second switch is a NMOS transistor.

12. The shift circuit of claim 6, wherein the latch unit includes:
a first inverter for inverting an output signal of the buffer unit and outputting the inverted signal to a first node;
a second inverter for inverting an output signal of the first node; and
a transfer element for transferring an output signal of the second inverter to an input terminal of the first inverter in response to the clock signal.

13. The shift circuit of claim 12, wherein the second inverter includes:
a pull-up element provided between a power supply voltage terminal and an output node for pull-up driving the output node in response to a signal of the first node; and
a pull-down element provided between the output node and a ground voltage terminal for pull-down driving the output node in response to the signal of the second node.

14. The shift circuit of claim 13, wherein the pull-up element is a PMOS transistor and the pull-down element is a NMOS transistor.

15. The shift circuit of claim 12, wherein the transfer element is provided between an output terminal of the second inverter and an output terminal of the buffer unit and turned on in response to the clock signal.

16. A shift circuit comprising:
a transfer buffer for buffering a signal on a first node and transferring the buffered signal to a second node;
a feedback buffer for feeding back the buffered signal on the second node to the first node; and
a feedback determination unit for determining an operation of the feedback buffer in response to a clock signal.

17. The shift circuit of claim 16, wherein the transfer buffer is an inverter.

18. The shift circuit of claim 16, wherein the feedback buffer includes:
a pull-up element provided between a power supply voltage terminal and an output node for pull-up driving the output node in response to an input signal; and
a pull-down element provided between the output node and a ground voltage terminal pull-down driving the output node in response to the input signal.

19. The shift circuit of claim 16, wherein the feedback determination unit is disposed between an output terminal of the feedback buffer and the first node and is turned on in response to the clock signal.

20. A shift circuit for transferring data comprising:
a signal transfer path for transferring a signal; and
a latch unit for latching the signal on the signal transfer path, wherein the latch unit includes:
a feedback loop provided on the signal transfer path
a plurality of inverters disposed on the feedback loop for inverting the signal on the signal transfer path; and
at least one switch for selectively coupling the feedback loop to the signal transfer path in response to a control signal.

21. The shift circuit of claim 20, wherein the control signal is a clock signal to control a signal transfer gate which is provided for the signal transfer path.
